(19) United States
(12) Patent Application Publication
(10) Pub. No.: US 2026/0121591 A1
(43) Pub. Date: Apr. 30, 2026

(54) DIFFERENTIAL AMPLIFIER, OPERATIONAL AMPLIFIER CIRCUIT, AND ELECTRONIC DEVICE

(71) Applicant: Jiangsu Huixian Display Technology Co., Ltd., Kunshan (CN)

(72) Inventors: Enqing GUO, Kunshan (CN); Cuili GAI, Kunshan (CN); Yusheng LIU, Kunshan (CN); Yun CHENG, Kunshan (CN)

(73) Assignee: Jiangsu Huixian Display Technology Co., Ltd., Kunshan (CN)

(21) Appl. No.: 19/432,177

(22) Filed: Dec. 24, 2025

(30) Foreign Application Priority Data
Dec. 26, 2024 (CN) 202411944347.1

(51) Int. Cl. H03F 1/32; H03F 3/45

(52) U.S. Cl. CPC H03F 1/3205; H03F 3/45273; H03F 2200/525

(57) ABSTRACT

The present disclosure discloses a differential amplifier, an operational amplifier circuit, and an electronic device. The differential amplifier includes: a differential input module, a load module, and an isolation module. The differential input module is configured with a first bias current and includes a first input terminal, a second input terminal, a first amplification node, and a second amplification node. The load module includes a first connection node and a second connection node, where the first connection node is connected to the first amplification node, and the second connection node serves as an output terminal of the differential amplifier. The isolation module is connected to the second amplification node and the second connection node, and a control terminal of the isolation module is connected to the first connection node. A voltage variation at the first connection node is negatively correlated with a conduction level of the isolation module.

### CROSS-REFERENCE TO RELATED APPLICATIONS

This application claims priority to Chinese Patent Application No. 202411944347.1, filed on December 26, 2024, which is incorporated herein by reference in its entirety.

### FIELD

The present disclosure relates to the field of amplifier circuit technology, and in particular to a differential amplifier, an operational amplifier circuit, and an electronic device.

### BACKGROUND

Currently, due to the kink effect in a transistor of an amplifier circuit, when a source-drain voltage difference (denoted as Vds) of the transistor is excessive, an operating current in a saturation region of the transistor increases significantly as Vds increases. When the transistor operates in the saturation region, an equivalent resistance is low, resulting in a low amplification factor of the amplifier circuit.

### SUMMARY

The present disclosure provides a differential amplifier, an operational amplifier circuit, and an electronic device, to improve an amplification factor of the circuit.

An embodiment of the present disclosure provides a differential amplifier, including:

a differential input module configured with a first bias current and includes a first input terminal, a second input terminal, a first amplification node, and a second amplification node, the first input terminal being configured with an input signal, the second input terminal being configured with a differential mode signal of the input signal, the first amplification node being configured to output an inverted amplified signal of the input signal, and the second amplification node being configured to output an in-phase amplified signal of the input signal; a load module including a first connection node and a second connection node, the first connection node being connected to the first amplification node, and the second connection node serving as an output terminal of the differential amplifier; and an isolation module connected to the second amplification node and the second connection node, a control terminal of the isolation module being connected to the first connection node, where a voltage variation at the first connection node is negatively correlated with a conduction level of the isolation module.

An embodiment of the present disclosure further provides an operational amplifier circuit, including:

a differential amplifier; an output module including a first control node and a third amplification node, the first control node being connected to an output terminal of the differential amplifier, and the third amplification node being configured to output an inverted amplified signal of a signal at the output terminal of the differential amplifier; and a voltage control module including a second control node, an input node, and an output node, the second control node being configured with a fixed voltage signal, the input node being connected to the third amplification node, the output node being configured with a second bias current, and the output node serving as an output terminal of the operational amplifier circuit; and the voltage control module being controlled by the fixed voltage signal to stably output a voltage of the third amplification node at the output node.

An embodiment of the present disclosure further provides an electronic device, including: an amplifier circuit including the differential amplifier provided in any embodiment of the present disclosure, or the operational amplifier circuit provided in any embodiment of the present disclosure.

In the differential amplifier provided in this embodiment of the present disclosure, the differential input module, the load module, and the isolation module are provided. The differential input module and the load module constitute a basic amplifier circuit structure, and a first bias current is equivalent to a stable bias signal provided to the differential input module. The isolation module may be configured to control a level of isolation between the second amplification node and the second connection node. By setting the voltage variation at the first connection node to be negatively correlated with the conduction level of the isolation module, the second connection node is allowed to follow a voltage difference between the first input terminal and the second input terminal with a larger voltage variation range, thereby enhancing an amplification factor of the differential-structure amplifier circuit, that is, improving the amplification factor of the differential amplifier.

### BRIEF DESCRIPTION OF THE DRAWINGS

FIG. 1 is a schematic structural diagram of a differential amplifier according to an embodiment of the present disclosure;

FIG. 2 is a schematic structural diagram of another differential amplifier according to an embodiment of the present disclosure;

FIG. 3 is a schematic structural diagram of still another differential amplifier according to an embodiment of the present disclosure;

FIG. 4 is a schematic structural diagram of still another differential amplifier according to an embodiment of the present disclosure;

FIG. 5 is a schematic structural diagram of still another differential amplifier according to an embodiment of the present disclosure;

FIG. 6 is a schematic structural diagram of an operational amplifier circuit according to an embodiment of the present disclosure;

FIG. 7 is a schematic structural diagram of another operational amplifier circuit according to an embodiment of the present disclosure;

FIG. 8 is a schematic structural diagram of still another operational amplifier circuit according to an embodiment of the present disclosure;

FIG. 9 is a schematic structural diagram of still another operational amplifier circuit according to an embodiment of the present disclosure;

FIG. 10 is a schematic structural diagram of still operational amplifier circuit according to an embodiment of the present disclosure;

FIG. 11 is a schematic structural diagram of still another operational amplifier circuit according to an embodiment of the present disclosure;

FIG. 12 is a schematic structural diagram of still another operational amplifier circuit according to an embodiment of the present disclosure;

FIG. 13 is a schematic structural diagram of still another operational amplifier circuit according to an embodiment of the present disclosure;

FIG. 14 is a schematic structural diagram of still another operational amplifier circuit according to an embodiment of the present disclosure;

FIG. 15 is a schematic structural diagram of still another operational amplifier circuit according to an embodiment of the present disclosure;

FIG. 16 is a schematic structural diagram of still another operational amplifier circuit according to an embodiment of the present disclosure;

FIG. 17 is a schematic structural diagram of still another operational amplifier circuit according to an embodiment of the present disclosure;

FIG. 18 is a curve graph of voltage characteristics of key node in an operational amplifier circuit according to an embodiment of the present disclosure;

FIG. 19 is a curve graph of voltage characteristics of key nodes in another operational amplifier circuit according to an embodiment of the present disclosure;

FIG. 20 is a curve graph of voltage characteristics of key nodes in still another operational amplifier circuit according to an embodiment of the present disclosure;

FIG. 21 is a comparative curve graph of voltage characteristics of key nodes in an operational amplifier circuit according to an embodiment of the present disclosure and a comparative example; and

FIG. 22 is a schematic structural diagram of an electronic device according to an embodiment of the present disclosure.

### DETAILED DESCRIPTION OF THE EMBODIMENTS

An embodiment of the present disclosure provides a differential amplifier. FIG. 1 is a schematic structural diagram of a differential amplifier according to an embodiment of the present disclosure. Referring to FIG. 1, the differential amplifier includes: a differential input module 210, a load module 220, and an isolation module 240. The differential input module 210 is configured with a first bias current I1. The differential input module 210 includes a first input terminal IN1, a second input terminal IN2, a first amplification node N1, and a second amplification node N2. The first input terminal IN1 is configured with an input signal, the second input terminal IN2 is configured with a differential mode signal of the input signal, the first amplification node N1 is configured to output an inverted amplified signal of the input signal, and the second amplification node N2 is configured to output an in-phase amplified signal of the input signal. The load module 220 includes a first connection node N3 and a second connection node N4, where the first connection node N3 is connected to the first amplification node N1, and the second connection node N4 serves as an output terminal OUT of the differential amplifier. The isolation module 240 is connected to the second amplification node N2 and the second connection node N4. In other words, the isolation module 240 is connected between the second amplification node N2 and the second connection node N4. A control terminal of the isolation module 240 is connected to the first connection node N3. The isolation module 240 controls a conduction level of the isolation module 240 based on a voltage of the first connection node N3, and a voltage variation at the first connection node N3 is negatively correlated with the conduction level of the isolation module 240.

The differential amplifier is an amplifier circuit using a differential input. The differential input module 210 may include a bias node, and the first bias current I1 is connected to the bias node. A power terminal of the load module 220 may be configured with (or provided with) a first power signal. The differential input module 210 and the load module 220 may both include transistors, such as thin-film transistors (TFTs). The differential input module 210 may include two transistors connected between the bias node and the first amplification node N1, and between the bias node and the second amplification node N2, respectively, and is configured to control, based on signals received at the first input terminal IN1 and the second input terminal IN2, currents output from the first amplification node N1 and the second amplification node N2, respectively. The load module 220 may include two transistors connected between the power terminal of the load module 220 and the first connection node N3, and between the power terminal of the load module 220 and the second connection node N4, respectively, and the transistors are respectively equivalent to load resistances between the power terminal of the load module 220 and the first connection node N3, and between the power terminal of the load module 220 and the second connection node N4.

For example, the operating principle of the differential amplifier is as follows: As a voltage difference between the first input terminal IN1 and the second input terminal IN2 increases, the currents output from the first amplification node N1 and the second amplification node N2 change in opposite directions, for example, one increases while the other decreases, with the current variation gradually increasing; and during this process, in cooperation with the function of the load module 220, voltages at the first connection node N3 and the second connection node N4 change in opposite directions, with the voltage variation gradually increasing. The voltage at the second connection node N4 of the load module 220 serves as an output voltage at the output terminal OUT of the differential amplifier.

Further, by configuring the isolation module 240, the second amplification node N2 and the second connection node N4 can be separated from each other. The conduction level of the isolation module 240 determines a level of isolation between the second amplification node N2 and the second connection node N4. The higher the conduction level of the isolation module 240, the more the voltage at the second connection node N4 aligns with the voltage at the second amplification node N2 The lower the conduction level of the isolation module 240, the less the voltage at the second connection node N4 is affected by the second amplification node N2. The voltage at the second connection node N4 can be determined to a greater extent based on the current received at the second connection node N4 and its connected load, to ensure that the voltage at the second connection node N4 is essentially unaffected by the pull of the voltage at the second amplification node N2. Therefore, by setting the voltage variation at the first connection node N3 to be negatively correlated with the conduction level of the isolation module 240, during the operation of the differential amplifier, when the voltage variation at the first connection node N3 increases, the conduction level of the isolation module 240 decreases, thereby allowing for a more stable voltage at the second amplification node N2 and enabling the second connection node N4 to achieve a larger voltage variation range. Compared to the case where the isolation module 240 is not arranged, the arrangement of the isolation module 240 may allow for a larger voltage variation at the second connection node N4 when the voltage difference between the first input terminal IN1 and the second input terminal IN2 increases by the same amount, thereby enhancing the amplification factor of the differential amplifier.

A specific operation process of the isolation module 240 may be seen in the following examples: The power terminal of the load module 220 is connected to a first power signal, one end of a component providing the first bias current I1 is connected to a bias node of the differential input module 210, and the other end is connected to a second power signal. The first power signal and the second power signal have different voltages. For example, the first power signal has a low voltage and the second power signal has a high voltage. On this basis, the variation trend of the conduction level of the isolation module 240 aligns with the variation trend of the conduction level between the bias node and the second amplification node N2. When the conduction between the bias node and the second amplification node N2 tends to turn off, causing the current output from the second amplification node N2 to gradually decrease, the voltage at the second amplification node N2 drops, the current output from the first amplification node N1 gradually increases, and the voltage at the first connection node N3 gradually increases. In this case, the isolation module 240 gradually tends to turn off, causing the voltage at the second connection node N4 to be lower than the voltage at the second amplification node N2, with the voltage difference gradually increasing. Therefore, in the case where the voltage variation at the second input terminal IN2 is identical, compared to the case where the isolation module 240 is not arranged, the arrangement of the isolation module 240 may allow the second connection node N4 to achieve a lower voltage and a larger voltage variation, which is equivalent to enhancing the amplification factor of the differential amplifier.

In the differential amplifier provided in this embodiment of the present disclosure, the differential input module 210, the load module 220, and the isolation module 240 are arranged. The differential input module 210 and the load module 220 constitute a basic amplifier circuit structure, and the first bias current I1 is equivalent to a stable bias signal provided to the differential input module 210. The isolation module 240 may be configured to control the level of isolation between the second amplification node N2 and the second connection node N4. By setting the voltage variation at the first connection node N3 to be negatively correlated with the conduction level of the isolation module 240, the second connection node N4 is allowed to follow the voltage difference between the first input terminal IN1 and the second input terminal IN2 with a larger voltage variation range, thereby enhancing the amplification factor of the differential-structure amplifier circuit, that is, improving the amplification factor of the differential amplifier.

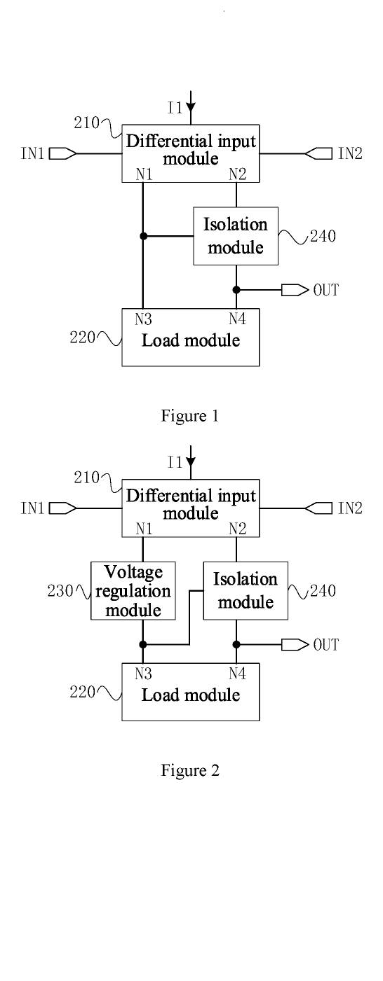

FIG. 2 is a schematic structural diagram of another differential amplifier according to an embodiment of the present disclosure. Referring to FIG. 2, in one embodiment, the differential amplifier further includes a voltage regulation module 230. The voltage regulation module 230 is connected to the first amplification node N1 and the first connection node N3, or the voltage regulation module 230 is connected between the first amplification node N1 and the first connection node N3. The voltage regulation module 230 is configured to stabilize the voltage at the first amplification node N1.

In this embodiment, by configuring the voltage regulation module 230 to stabilize the voltage at the first amplification node N1, an operation state of a transistor between the bias node and the first amplification node N1 may be stabilized to avoid unnecessary current fluctuations at the first amplification node N1 due to large voltage differences during operation, thereby ensuring the stability of the currents output from the first amplification node N1 and the second amplification node N2, the stability of the operation state of the differential amplifier, and the reliability of its amplification function.

The following provides an exemplary description of specific structures of various modules in the differential amplifier, which is not intended to limit the scope of the present disclosure.

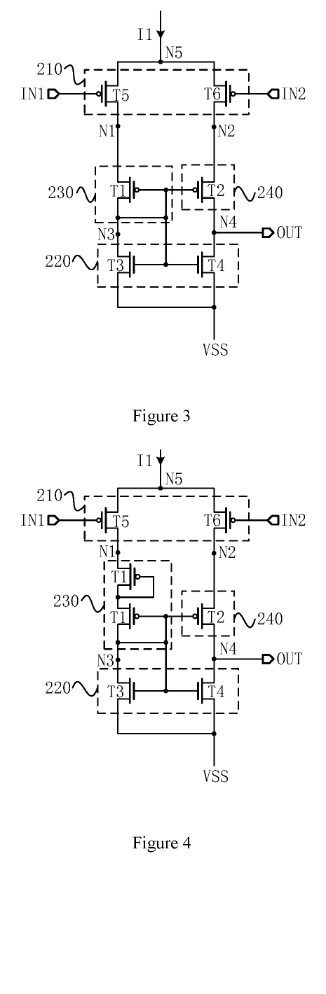

FIG. 3 is a schematic structural diagram of still another differential amplifier according to an embodiment of the present disclosure. Referring to FIG. 3, in one embodiment, the differential input module 210 includes: a fifth transistor T5 and a sixth transistor T6. A first electrode of the fifth transistor T5 and a first electrode of the sixth transistor T6 are both configured with the first bias current I1, for example, both connected to a bias node N5, a gate of the fifth transistor T5 is connected to the first input terminal IN1, a second electrode of the fifth transistor T5 is connected to the first amplification node N1, a gate of the sixth transistor T6 is connected to the second input terminal IN2, and a second electrode of the sixth transistor T6 is connected to the second amplification node N2. For example, the fifth transistor T5 and the sixth transistor T6 have the same channel type. In FIG. 2, illustratively, both the fifth transistor T5 and the sixth transistor T6 are P-type transistors. The fifth transistor T5 and the sixth transistor T6 have the same channel width-to-length ratio to ensure the normal operation of the differential input module 210.

The load module 220 includes: a third transistor T3 and a fourth transistor T4. A first electrode of the third transistor T3 is connected to the first connection node N3, a second electrode of the third transistor T3 is configured with a first power signal VSS, a gate of the third transistor T3 is connected to the first electrode of the third transistor T3 and a gate of the fourth transistor T4, a first electrode of the fourth transistor T4 is connected to the second connection node N4, and a second electrode of the fourth transistor T4 is configured with the first power signal VSS. In this way, a current mirror circuit structure is constituted by the third transistor T3 and the fourth transistor T4. For example, the second electrode of the third transistor T3 and the second electrode of the fourth transistor T4 are both connected to a first power terminal of the differential amplifier, and the first power terminal is connected to the first power signal VSS. The third transistor T3 and the fourth transistor T4 have the same channel type. In FIG. 2, illustratively, both the third transistor T3 and the fourth transistor T4 are N-type transistors.

In this embodiment, a current mirror circuit and the differential amplifier constitute an amplification structure in the differential amplifier, where the transconductance of the fifth transistor T5 and the sixth transistor T6, and output resistances of the sixth transistor T6 and the fourth transistor T4 determine the amplification factor of the differential amplifier. When the foregoing transistors are all TFTs, the low transconductance and small output resistances of the TFTs result in a low amplification factor of the differential amplifier. According to this embodiment of the present disclosure, adding the voltage regulation module 230 and the isolation module 240 to the differential amplifier is equivalent to increasing an equivalent output resistance of the differential amplifier while enhancing the stability of the differential amplifier, thereby improving the amplification factor of the differential amplifier. The following provides an exemplary description of possible structures of the voltage regulation module 230 and the isolation module 240.

Still referring to FIG. 3, in one embodiment, the voltage regulation module 230 includes: at least one first transistor T1 in a diode-connected form, connected between the first amplification node N1 and the first connection node N3. FIG. 3 illustratively shows the case where the voltage regulation module 230 includes one first transistor T1, which is not intended to limit the present disclosure. In other implementations, referring to FIG. 4, when the voltage regulation module 230 includes a plurality of (two are illustratively shown in the figure) first transistors T1 in the diode-connected form, the plurality of first transistors T1 are connected in series between the first amplification node N1 and the first connection node N3.

In this embodiment, by introducing the at least one first transistor T1 in the diode-connected form on the basis of the current mirror circuit, the introduction of a high-resistance resistor in the differential amplifier can be avoided. The first transistor T1 based on the diode-connected form can well stabilize direct-current operating points of the transistors in the differential amplifier.

Based on the different channel types of the first transistor T1, its specific connection method in the circuit may vary slightly, which is described in detail below.

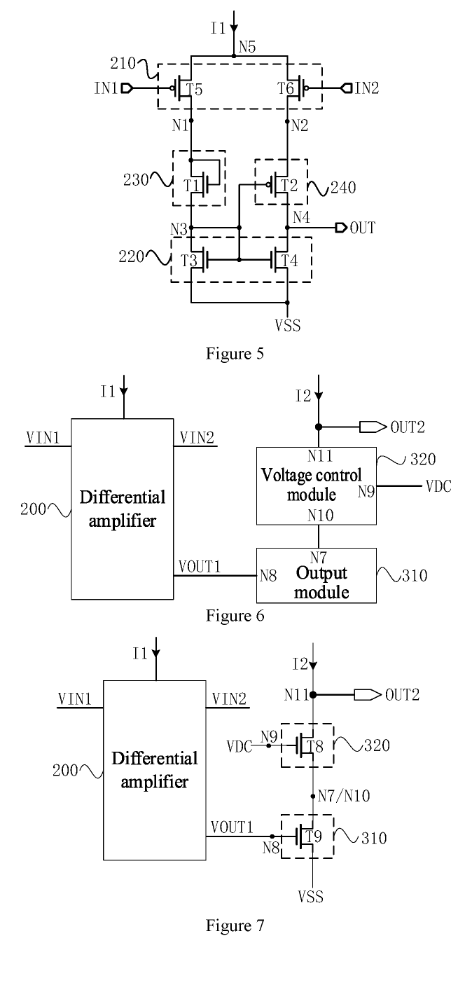

For ease of description, the electrode of the first transistor T1 connected (e.g., directly or indirectly through other first transistors T1) to the first amplification node N1 is referred to as the first electrode of the first transistor T1, and the electrode of the first transistor T1 connected (e.g., directly or indirectly through other first transistors T1) to the first connection node N3 is referred to as the second electrode of the first transistor T1. Referring to FIG. 3 and FIG. 4, when the first transistor T1 is a P-type transistor, a gate of the first transistor T1 is connected to the second electrode of the first transistor T1. Referring to FIG. 5, when the first transistor T1 is an N-type transistor, the gate of the first transistor T1 is connected to the first electrode of the first transistor T1.

Still referring to FIG. 3 to FIG. 5, in one embodiment, the isolation module 240 includes: a second transistor T2. A gate of the second transistor T2 is connected to the first connection node N3, a first electrode of the second transistor T2 is connected to the second amplification node N2, and a second electrode of the second transistor T2 is connected to the second connection node N4. In this embodiment, by configuring the isolation module 240 to include one transistor, the structure of the isolation module 240 is simple and easy to implement.

It should be understood that, referring to FIG. 3 to FIG. 5, the differential amplifier includes six transistors and exhibits excellent symmetry, thereby effectively preventing zero-offset drift in the differential amplifier, and ensuring that when there is no voltage difference between the first input terminal IN1 and the second input terminal IN2, the voltage at the output terminal OUT of the differential amplifier is as close to 0V as possible.

It should be noted that when a plurality of first transistors T1 are arranged, an operating range of the input signal of the differential amplifier is limited to some degree. Therefore, the number of first transistors T1 can be selected by comprehensively considering voltage regulation requirements at the first amplification node N1 and the operating range of the input signal of the differential amplifier. In addition, considering the symmetry of the differential amplifier, only one first transistor T1 may be arranged.

Based on the foregoing implementations, in one embodiment, the fourth transistor T4 and the second transistor T2 have different channel types. For example, the third transistor T3 and the fourth transistor T4 are both N-type transistors, and the second transistor T2 is a P-type transistor. It should be understood that the second connection node N4 serves as the output terminal OUT of the differential amplifier. From the structure of an output portion of the differential amplifier, setting the second transistor T2 and the fourth transistor T4 with different channel types is equivalent to applying an inverter design to the output terminal of the differential amplifier, which can effectively increase the output resistance of the differential amplifier, thereby enhancing the amplification factor of the differential amplifier.

In one embodiment, the differential amplifier may include thin-film transistors. A flexible electronic technology using TFT processes has characteristics such as low cost, large substrate area, and flexibility for bending, facilitating the application of the differential amplifier in scenarios with high requirements on cost and product space utilization. Specifically, the differential input module 210, the load module 220, and the isolation module 240 may all include thin-film transistors. Further, when the differential amplifier includes the voltage regulation module 230, the voltage regulation module 230 also includes thin-film transistors. That is, the first transistor T1 to the sixth transistor T6 may all be thin-film transistors.

An embodiment of the present disclosure further provides an operational amplifier circuit. FIG. 6 is a schematic structural diagram of an operational amplifier circuit according to an embodiment of the present disclosure. Referring to FIG. 6, the operational amplifier circuit includes: a differential amplifier 200, an output module 310, and a voltage control module 320.

The differential amplifier 200 may include a differential amplifier of any structure. The differential amplifier 200 is configured with a first bias current I1, an input signal VIN1, and a differential mode signal VIN2 of the input signal. In one embodiment, a first input terminal of the differential amplifier 200 is connected to the input signal VIN1, a second input terminal is connected to the differential mode signal VIN2 of the input signal, a bias node is connected to the first bias current I1, and an output terminal outputs a first amplified signal VOUT1. The output module 310 includes a first control node N8 and a third amplification node N7. The first control node N8 is connected to the output terminal of the differential amplifier 200. The third amplification node N7 is configured to output an inverted amplified signal of a signal at the output terminal of the differential amplifier 200, that is, to output an inverted amplified signal of the first amplified signal VOUT1. The voltage control module 320 includes a second control node N9, an input node N10, and an output node N11. The second control node N9 is configured with a fixed voltage signal VDC, the input node N10 is connected to the third amplification node N7, the output node N11 is configured with a second bias current I2, and the output node N11 serves as an output terminal OUT2 of the operational amplifier circuit. The voltage control module 320 is configured to stabilize a voltage at the third amplification node N7, in one embodiment, to stably output the voltage of the third amplification node N7 at the output node N11 under the control of the fixed voltage signal VDC.

In the operational amplifier circuit provided in this embodiment of the present disclosure, the differential amplifier 200 serves as a first-stage amplifier circuit in the operational amplifier circuit. The output module 310, in cooperation with the voltage control module 320, constitutes an output-stage amplifier circuit within the operational amplifier circuit. The output module 310 may further amplify and output the first amplified signal VOUT1 output by the differential amplifier 200. The two-stage amplification is used to effectively enhance the amplification factor of the operational amplifier circuit. By stabilizing the voltage at the third amplification node N7, the voltage control module 320 can suppress the voltage range of the voltage at the third amplification node N7, to suppress the kink effect in the transistor inside the output module 310,thereby improving the linear relationship between the circuit input and output signals, reducing signal transmission distortion, and avoiding the impact of the kink effect on the amplification factor of the output module 310.

FIG. 7 is a schematic structural diagram of another operational amplifier circuit according to an embodiment of the present disclosure. Referring to FIG. 7, in one embodiment, the output module 310 includes: a ninth transistor T9. A gate of the ninth transistor T9 is connected to the output terminal of the differential amplifier 200, a first electrode of the ninth transistor T9 is connected to the third amplification node N7, and a second electrode of the ninth transistor T9 is configured with the first power signal VSS. For example, the operational amplifier circuit includes a first power terminal connected to the first power signal VSS. In this embodiment, by configuring the output module 310 to include one transistor, the structure of the output module 310 is simple and easy to implement. Based on the foregoing implementations, in one embodiment, the ninth transistor T9 is a thin-film transistor to reduce the cost of the operational amplifier circuit.

Research has found that due to the kink effect in the thin-film transistor, there is nonlinearity in the input-output relationship in an amplification region of the ninth transistor T9, which may cause signal distortion. To solve the signal distortion issue, in this embodiment of the present disclosure, the voltage control module 320 is added to the output-stage amplifier circuit to improve the linearity of the input-output relationship and reduce signal transmission distortion.

In one embodiment, still referring to FIG. 7, the voltage control module 320 may include: an eighth transistor T8. A first electrode of the eighth transistor T8 is connected to the output node N11, which is then connected to the output terminal OUT2 of the operational amplifier circuit. A second electrode of the eighth transistor T8 is connected to the input node N10, that is, connected to the third amplification node N7. A gate of the eighth transistor T8 is connected to the second control node N9, which is then configured with the fixed voltage signal VDC. The eighth transistor T8 stably outputs the voltage of the third amplification node N7 at the output node N11 under the control of the fixed voltage signal VDC. For example, the ninth transistor T9 and the eighth transistor T8 have the same channel type. As shown in FIG. 7, the ninth transistor T9 and the eighth transistor T8 may both be N-type transistors.

The fixed voltage signal VDC has a stable voltage. When a difference between the fixed voltage signal VDC and the voltage at the third amplification node N7 (equivalent to a gate-source voltage difference of the eighth transistor T8) controls the eighth transistor T8 to turn on, due to the stable voltage of the fixed voltage signal VDC and the minimal variation in the gate-source voltage difference of the eighth transistor T8, the voltage variation range at the third amplification node N7 can be effectively limited, thereby suppressing current fluctuations at the third amplification node N7 caused by the kink effect in the ninth transistor T9, and improving the amplification factor and linearity of the output-stage amplifier circuit.

For example, the voltage of the fixed voltage signal VDC is different from the voltage at the output terminal of the differential amplifier 200 to prevent gate voltages of the eighth transistor T8 and the ninth transistor T9 from being identical, which may result in a small gate-source voltage difference for the eighth transistor T8 and prevent the eighth transistor from fully turning on. The voltage of the fixed voltage signal VDC being different from the voltage at the output terminal of the differential amplifier 200 may in one embodiment be: the voltage of the fixed voltage signal VDC is not within a normal output voltage range of the output terminal of the differential amplifier 200. For example, when the ninth transistor T9 and the eighth transistor T8 are both N-type transistors, the voltage of the fixed voltage signal VDC may be higher than the voltage at the output terminal of the differential amplifier 200, for example, higher than a maximum voltage that the differential amplifier 200 can output when receiving voltages within the normal operating voltage range, to ensure full conduction of the eighth transistor T8. A specific voltage value of the fixed voltage signal VDC may be determined based on an operating voltage range of the eighth transistor T8, in conjunction with simulation analysis of the circuit.

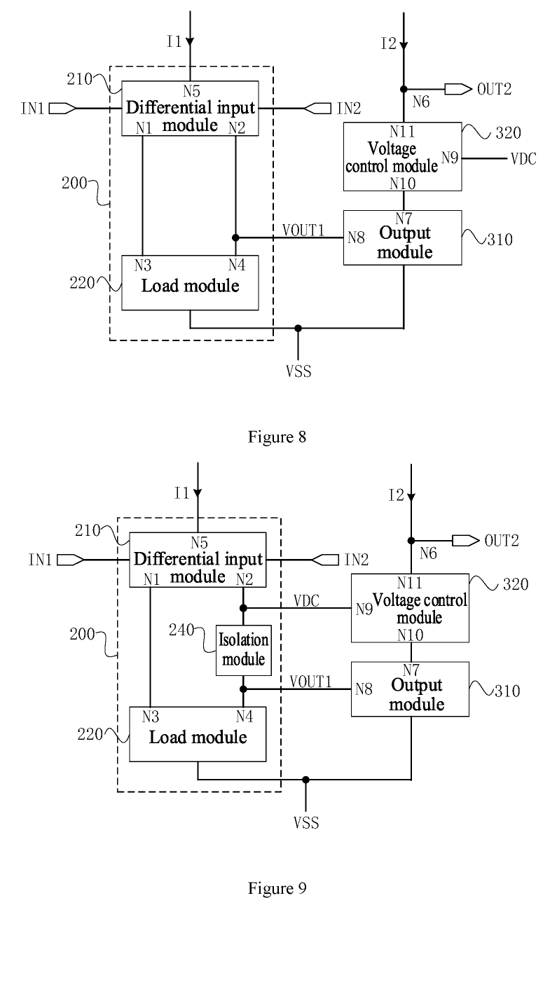

FIG. 8 is a schematic structural diagram of still another operational amplifier circuit according to an embodiment of the present disclosure. Referring to FIG. 8, in one embodiment, the differential amplifier 200 includes: a differential input module 210 and a load module 220. The differential input module 210 is configured with the first bias current I1, for example, the bias node N5 is connected to the first bias current I1. The differential input module 210 includes a first input terminal IN1, a second input terminal IN2, a first amplification node N1, and a second amplification node N2. The first input terminal IN1 is configured with an input signal, the second input terminal IN2 is configured with a differential mode signal of the input signal, the first amplification node N1 is configured to output an inverted amplified signal of the input signal, and the second amplification node N2 is configured to output an in-phase amplified signal of the input signal. The load module 220 includes a first connection node N3 and a second connection node N4, the first connection node N3 is connected to the first amplification node N1, and the second connection node N4 serves as an output terminal OUT of the differential amplifier and is configured to output a first amplified signal VOUT1. In this implementation, the fixed voltage signal VDC may be provided by a separately arranged fixed voltage signal line; and the voltage of the fixed voltage signal VDC may be set to be different from that of the output terminal of the differential amplifier 200. It should be understood that the differential input module 210 and the load module 220 may have the structures given in any of the foregoing implementations, which will not be repeated herein.

In another implementation, in one embodiment, the differential amplifier 200 includes the structure of the differential amplifier provided in any of the foregoing implementations. For example, the differential amplifier 200 may include the differential input module 210, the load module 220, and the isolation module 240, and may further include the voltage regulation module 230.

In one embodiment, there are various manners for supplying the fixed voltage signal VDC. Exemplary descriptions of several of these manners are provided below, but are not intended to limit the present disclosure.

In one embodiment, an additional fixed voltage signal VDC may be introduced to ensure a stable potential at the second control node N9, preventing it from being affected by a circuit operating state, and ensuring the linearity of the operational amplifier circuit. This implementation is applicable to a differential amplifier 200 of any structure.

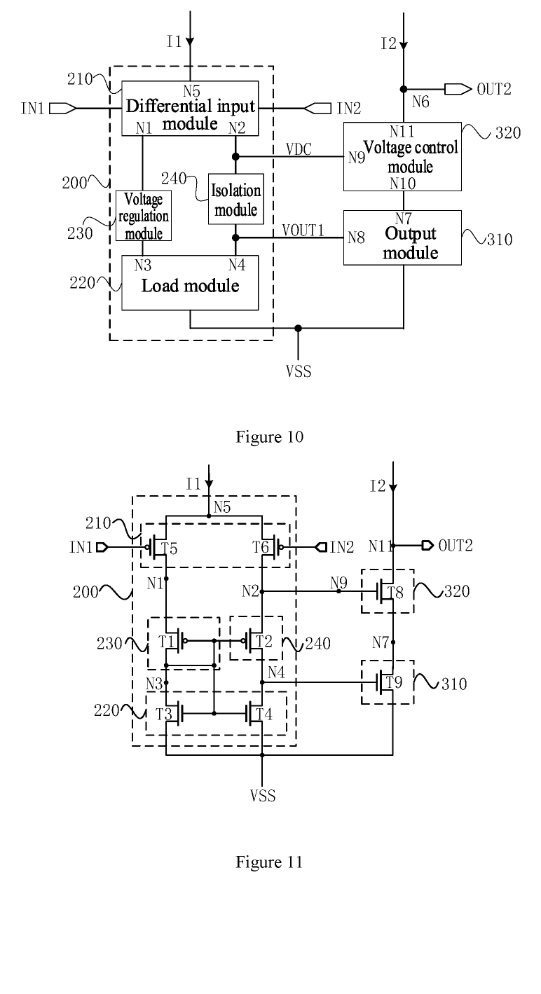

Referring to FIG. 9 to FIG. 11, in another implementation, in one embodiment, in the case where the differential amplifier 200 includes the differential input module 210, the load module 220, and the isolation module 240 (which may further include the voltage regulation module 230), the second amplification node N2 may provide the fixed voltage signal, and the second control node N9 may be directly connected to the second amplification node N2. Since the isolation module 240 (or the cooperation of the voltage regulation module 230 and the isolation module 240) in the differential amplifier 200 may function to stabilize the voltage of the second amplification node N2, the voltage at the second amplification node N2 itself becomes relatively stable and may be reused as the fixed voltage signal VDC. This arrangement allows an internal node voltage of the differential amplifier 200 to be reused as the fixed voltage signal VDC, thereby eliminating the need for an additional switch control signal and simplifying the structure of the operational amplifier circuit. Moreover, based on the presence of the isolation module 240, a voltage difference inherently exists between the second amplification node N2 and the output terminal of the differential amplifier 200, which results in a voltage difference between the second control node N9 and the first control node N8, thereby ensuring that the eighth transistor T8 is fully turned on when needed, and avoiding the issue of insufficient conduction of the eighth transistor T8 caused by a short circuit between the gates of the eighth transistor T8 and the ninth transistor T9.

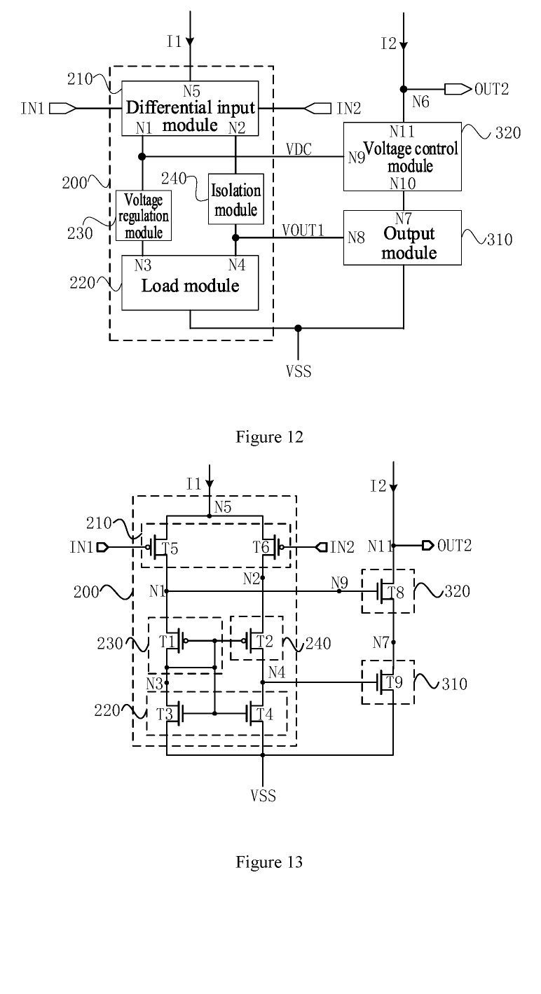

In still another implementation, in one embodiment, referring to FIG. 12 and FIG. 13, in the case where the differential amplifier 200 has the differential input module 210, the load module 220, the isolation module 240, and the voltage regulation module 230, the second amplification node N1 may provide the fixed voltage signal, and the second control node N9 may be directly connected to the first amplification node N1. Since the voltage regulation module 230 may function to stabilize the voltage at the first amplification node N1, the voltage at the first amplification node N1 of the differential input module 210 itself becomes relatively stable and may be reused as the fixed voltage signal VDC. This arrangement is also equivalent to reusing the internal node voltage of the differential amplifier 200 as the fixed voltage signal VDC, thereby simplifying the structure of the operational amplifier circuit.

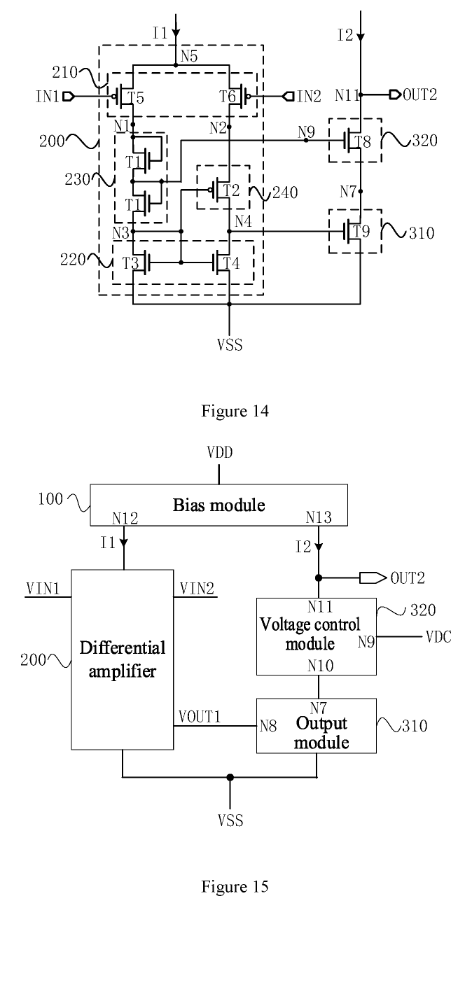

In still another implementation, in one embodiment, referring to FIG. 14, in the case where the voltage regulation module 230 includes at least two first transistors T1 connected in series in the diode-connected form, a connection node between any two adjacent first transistors T1 may provide the fixed voltage signal, and the second control node N9 may also be connected to the connection node between any two adjacent first transistors T1. Since any first transistor T1 in the diode-connected form has a voltage-stabilizing function, the connection node between any two adjacent first transistors T1 also has a relatively stable voltage, which may be reused as the fixed voltage signal VDC.

In another implementation, in one embodiment, when the differential amplifier 200 has any of the structures shown in FIGS. 9 to 14, a separate fixed voltage signal line may also be arranged to provide the fixed voltage signal VDC. The second control node N9 may be connected to the fixed voltage signal line; and the voltage of the fixed voltage signal VDC is different from the voltage at the output terminal of the differential amplifier. For example, when the differential amplifier 200 has the isolation module 240, the voltage value of the fixed voltage signal VDC may be equal to the voltage at the second amplification node N2 (or within the voltage variation range of the second amplification node N2); and when the differential amplifier 200 has the voltage regulation module 230 and the isolation module 240, the voltage value of the fixed voltage signal VDC may be equal to the voltage at the second amplification node N2 (or within the voltage variation range of the second amplification node N2), or equal to the voltage at the first amplification node N1 (or within the voltage variation range of the first amplification node N1), or between the voltage at the connection node between any two adjacent first transistors T1 and the voltage at the first amplification node N1.

FIG. 14 is a schematic structural diagram of still another operational amplifier circuit according to an embodiment of the present disclosure. Referring to FIG. 14, in one embodiment, the operational amplifier circuit further includes: a bias module 100 including a first bias output node N12 and a second bias output node N13. The first bias output node N12 is configured to output the first bias current I1, and the second bias output node N13 is configured to output the second bias current I2. An input terminal of the bias module 100, for example, is configured with a second power signal VDD. For example, the operational amplifier circuit includes a second power terminal connected to the second power signal VDD. In this embodiment, the bias module 100 may provide the corresponding bias currents to the differential amplifier 200 and the output-stage amplifier circuit.

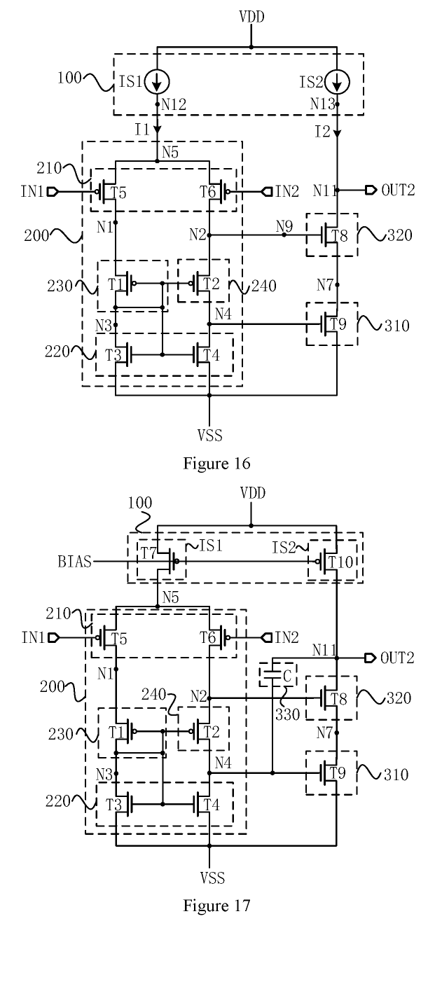

In one embodiment, referring to FIG. 16, the bias module 100 includes: a first current source IS1 and a second current source IS2. An output terminal of the first current source IS1 is connected to the first bias output node N12 for providing the first bias current I1. An output terminal of the second current source IS2 is connected to the second bias output node N13 for providing the second bias current I2.

Referring to FIG. 17, the first current source IS1 may include: a seventh transistor T7. A gate of the seventh transistor T7 is configured with a bias voltage BIAS, a first electrode of the seventh transistor T7 is configured with the second power signal VDD, and a second electrode of the seventh transistor T7 is connected to the output terminal of the first current source IS1. In this embodiment, by configuring the first current source IS1 to include one transistor, the structure of the first current source IS1 is simple and easy to implement.

The second current source IS2 includes: a tenth transistor T10. A gate of the tenth transistor T10 is configured with the bias voltage BIAS, a first electrode of the tenth transistor T10 is configured with the second power signal VDD, and a second electrode of the tenth transistor T10 is connected to the output terminal of the second current source IS2. In this embodiment, by configuring the second current source IS2 to include one transistor, the structure of the second current source IS2 is simple and easy to implement.

It should be understood that the operational amplifier circuit may include a bias terminal connected to the bias voltage BIAS; and during the operation of the operational amplifier circuit, the bias terminal provides a direct-current bias voltage BIAS, which ensures stable bias currents output from the first current source IS1 and the second current source IS2.

In one embodiment, the differential amplifier 200, the output module 310, and the voltage control module 320 all include thin-film transistors to reduce circuit costs. Further, the operational amplifier circuit further includes the bias module 100, which may also include thin-film transistors to reduce the circuit costs.

In one embodiment, referring to FIG. 17, the operational amplifier circuit further includes: a storage module 330 connected between the output terminal of the differential amplifier 200 and the output terminal OUT2 of the operational amplifier circuit and configured to stabilize an output signal of the circuit. The output module 310, the voltage control module 320, and the storage module 330 may jointly constitute the output-stage amplifier circuit. In one embodiment, the storage module 330 includes: a capacitor C connected between the output terminal of the differential amplifier 200 and the output terminal OUT2 of the operational amplifier circuit.

In summary, in the operational amplifier circuit provided in the embodiments of the present disclosure, the differential amplifier 200 serves as the first-stage amplifier circuit; the output module 310, the voltage control module 320, and the storage module 330 constitute the output-stage amplifier circuit; and the bias module 100 provides the bias currents to the two-stage amplifier circuits. The arrangement of the voltage regulation module 230, the isolation module 240, and the voltage control module 320 is equivalent to adding an equivalent output resistance to both the differential amplifier and the output-stage amplifier circuit, thereby providing a higher amplification factor of the operational amplifier and reducing signal transmission distortion. In one embodiment, the bias module 100, the differential input module 210, the load module 220, the voltage regulation module 230, the isolation module 240, the output module 310, and the voltage control module 320 all include thin-film transistors to reduce the circuit costs.

In one embodiment, referring to FIG. 17, in the operational amplifier circuit, the gate of the seventh transistor T7 and the gate of the tenth transistor T10 are both configured with the bias voltage BIAS, forming two current sources; the fifth transistor T5 and the sixth transistor T6 constitute the differential input module 210; the first transistors T1 and the third transistor T3 constitute at least two equivalent diodes connected in series; the second transistor T2 and the fourth transistor T4 constitute an inverter structure, increasing the amplification factor of the differential amplifier 200; the ninth transistor T9 serves as an output transistor, further amplifying the output signal of the differential amplifier 200, and outputting the output signal to the output terminal OUT2 of the operational amplifier circuit; and the eighth transistor T8 functions to stabilize the voltage at the third amplification node N7, reducing the impact of the kink effect in the ninth transistor T9, and improving the linearity of the input-output relationship.

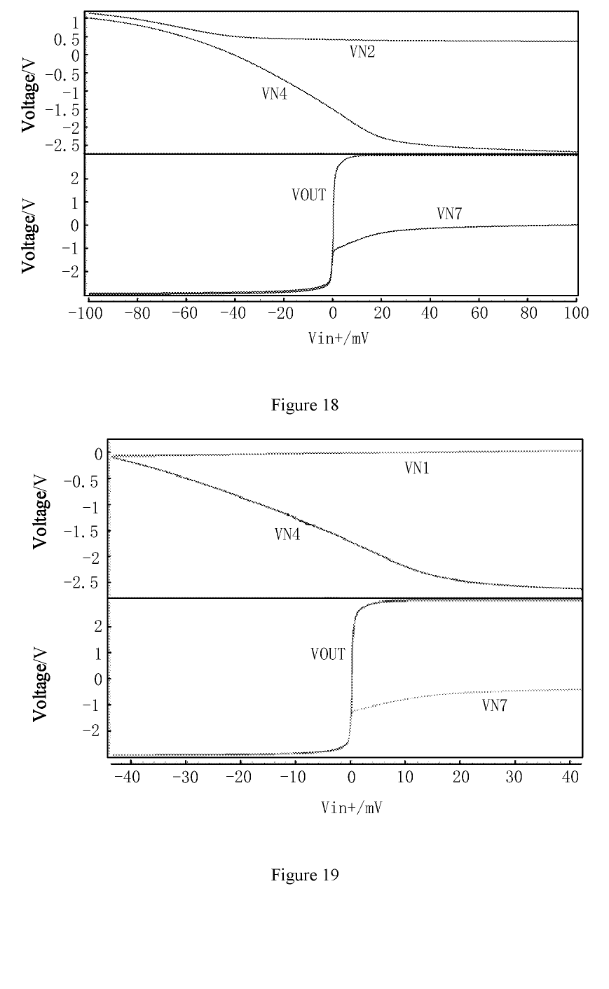

Taking the circuit structure in FIG. 17 as an example, in conjunction with a voltage curve of a key node in FIG. 18, the output voltage of the operational amplifier circuit is denoted as VOUT, and the specific operational principle of the operational amplifier circuit may be: in the case where the first input terminal IN1 is grounded and an actual input voltage (denoted as Vin+) is provided to the second input terminal IN2, as the actual input voltage Vin+ increases, the current through the sixth transistor T6 decreases and the current through the fifth transistor T5 increases, which results in an increase in the voltage at the first connection node N3, thereby causing the fourth transistor T4 to turn on more. Meanwhile, the second transistor T2 and the sixth transistor T6 tend to turn off, causing a voltage VN2 at the second amplification node N2 and a voltage VN4 at the second connection node N4 to decrease. Due to the blocking effect caused by the second transistor T2 tending to turn off, the decrease in the voltage VN2 at the second amplification node N2 is relatively slow. At the output terminal OUT2 of the operational amplifier circuit, due to the presence of the eighth transistor T8, a voltage VN7 at the third amplification node N7 is prevented from rising excessively and remains slightly lower than the voltage at the second amplification node N2, thereby effectively suppressing the kink effect in the ninth transistor T9, and improving the linear relationship between the input and output of the operational amplifier circuit.

FIG. 19 is a curve graph of key node voltage characteristics of another operational amplifier circuit according to an embodiment of the present disclosure. FIG. 19 is a curve graph of voltage characteristics obtained when the gate of the eighth transistor T8 in the circuit shown in FIG. 17 is modified to be connected to the first amplification node N1, with the first input terminal IN1 grounded and the actual input voltage Vin+ provided to the second input terminal IN2. FIG. 19 shows the relationships between the actual input voltage Vin+ and the voltage VN1 at the first amplification node N1, the voltage VN4 at the second connection node N4, the output voltage VOUT of the operational amplifier circuit, and the voltage VN7 at the third amplification node N7, respectively. As can be seen from FIG. 19, in the case where the gate of the eighth transistor T8 is connected to the first amplification node N1, since the voltage VN1 at the first amplification node N1 is relatively stable and not significantly different from the actual input voltage Vin+, it helps limit the voltage VN7 at the third amplification node N7 from rising excessively, thereby suppressing the kink effect in the ninth transistor T9.

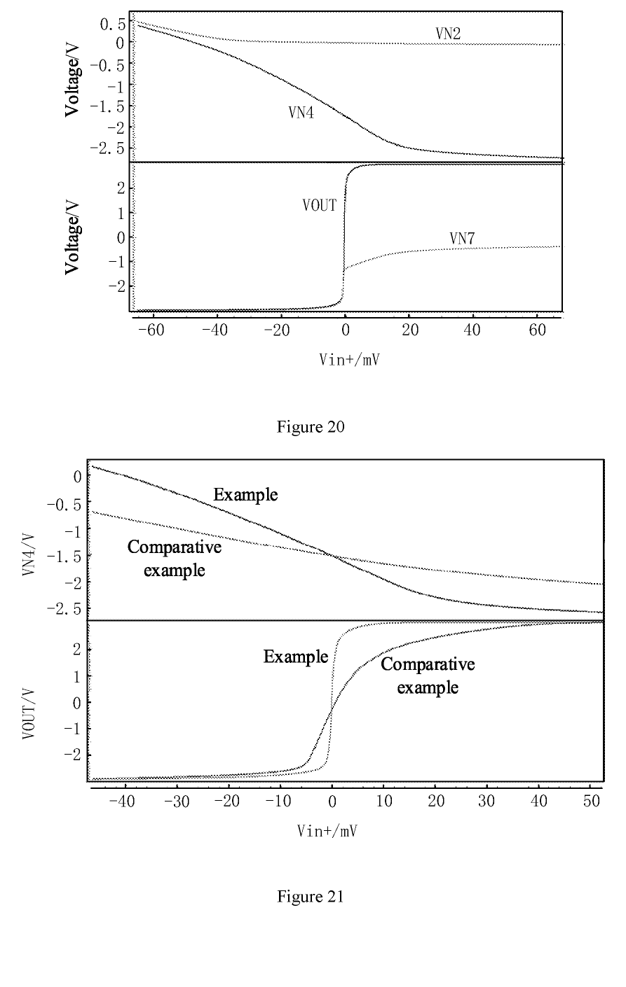

FIG. 20 is a curve graph of key node voltage characteristics of still another operational amplifier circuit according to an embodiment of the present disclosure. FIG. 20 is a curve graph of voltage characteristics obtained when the first transistor T1 in the circuit shown in FIG. 17 is changed to an N-type transistor, with the first input terminal IN1 grounded and the actual input voltage Vin+ provided to the second input terminal IN2. FIG. 20 shows the relationships between the actual input voltage Vin+ and the voltage VN2 at the second amplification node N2, the voltage VN4 at the second connection node N4, the output voltage VOUT of the operational amplifier circuit, and the voltage VN7 at the third amplification node N7, respectively. As can be seen from FIG. 20, in the case where the first transistor T1 is an N-type transistor, the essentially same result as shown in FIG. 18 can be still achieved, thereby ensuring the amplification factor and linearity of the operational amplifier circuit.

To verify the effect of the operational amplifier circuit provided in the embodiments of the present disclosure, the inventor conducted a simulation comparison of operating characteristics between the operational amplifier circuit provided in the embodiments of the present disclosure and a comparative example. In the embodiments of the present disclosure, the operational amplifier circuit shown in FIG. 17 is selected. In the comparative example, the first transistor T1, the second transistor T2, and the eighth transistor T8 in FIG. 17 are removed, which is equivalent to the first amplification node N1 being directly connected to the first connection node N3, the second amplification node N2 being directly connected to the second connection node N4, and the third amplification node N7 being directly connected to the output terminal OUT2 of the operational amplifier circuit. As can be seen from FIG. 21, in the operational amplifier circuit provided in this embodiment, the voltage VN4 at the second connection node N4, i.e., the output voltage of the differential amplifier 200, has a higher amplification factor. In the comparative example, as the actual input voltage Vin+ increases, the output voltage VOUT increases excessively slowly when approaching a high level. This is due to the onset of the kink effect, where the current through the ninth transistor T9 becomes difficult to suppress, leading to a nonlinear relationship between the input and output, and resulting in signal transmission distortion. In contrast, in this embodiment of the present disclosure, as the actual input voltage Vin+ increases, the output voltage VOUT increases rapidly when approaching the high level, which can effectively solve the foregoing distortion issue.

An embodiment of the present disclosure further provides an electronic device, including: an amplifier circuit. The amplifier circuit may be the differential amplifier provided in any embodiment of the present disclosure, or the operational amplifier circuit provided in any embodiment of the present disclosure, providing the corresponding beneficial effects.

For example, the electronic device may be: a radio frequency identification device, a music player, a display device, or any other electronic device that requires a built-in operational amplifier function. In the electronic device, the amplifier circuit may be used to constitute various components such as an integrator, a differentiator, a multiplier, an adder, an amplifier, and a voltage follower. For example, the electronic device may be a flexible electronic device, and the transistors in the amplifier circuit may all be thin-film transistors, thereby achieving applications in the flexible electronic aspect.

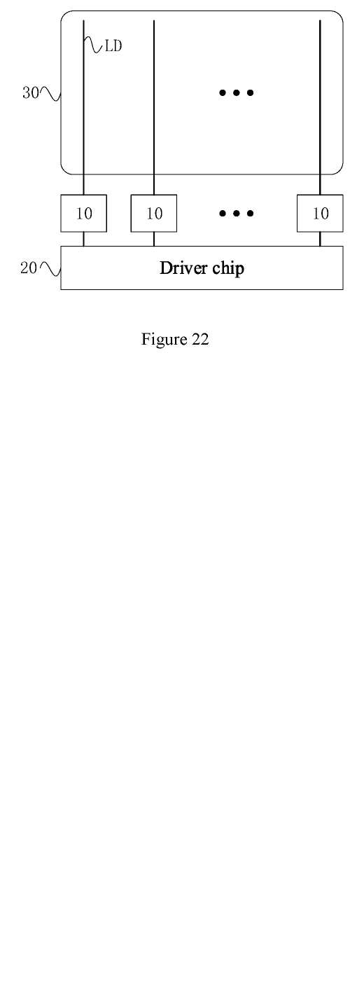

In a specific implementation, illustratively, the electronic device may be a display device. Referring to FIG. 22, the display device may include: a driver chip 20, a plurality of data lines LD, and a plurality of amplifier circuits 10, where the plurality of data lines LD and the plurality of amplifier circuits 10 may be connected in a one-to-one correspondence. In one embodiment, the amplifier circuit may be an operational amplifier circuit. A first input terminal and/or a second input terminal of a differential input module in the amplifier circuit 10 may be connected to the driver chip 20, and an output terminal of the amplifier circuit 10 is connected to the corresponding data line LD. The driver chip 20 transmits data signals to the data lines LD through the respective amplifier circuits 10. The plurality of data lines LD, for example, are arranged in a display panel 30, and configured to provide the data signals to sub-pixels (not shown in the figure) in the display panel, thereby achieving a display function of the display panel.

The foregoing specific implementations do not constitute a limitation on the scope of protection of the present disclosure. It should be understood in the art that various modifications, combinations, sub-combinations, and substitutions may be made according to design requirements and other factors. Any modifications, equivalent substitutions, or improvements made within the spirit and principle of the present disclosure should be included within the scope of protection of the present disclosure.

What is claimed is:

1. A differential amplifier, comprising:
a differential input module configured with a first bias current and comprising a first input terminal, a second input terminal, a first amplification node, and a second amplification node, the first input terminal being configured with an input signal, the second input terminal being configured with a differential mode signal of the input signal, the first amplification node being configured to output an inverted amplified signal of the input signal, and the second amplification node being configured to output an in-phase amplified signal of the input signal;
a load module comprising a first connection node and a second connection node, the first connection node being connected to the first amplification node, and the second connection node serving as an output terminal of the differential amplifier; and
an isolation module connected to the second amplification node and the second connection node, a control terminal of the isolation module being connected to the first connection node,
wherein a voltage variation at the first connection node is negatively correlated with a conduction level of the isolation module.

2. The differential amplifier according to claim 1, further comprising:
a voltage regulation module connected to the first amplification node and the first connection node, the voltage regulation module being configured to stabilize a voltage at the first amplification node.

3. The differential amplifier according to claim 2, wherein the voltage regulation module comprises a first transistor in a diode-connected form; or the voltage regulation module comprises a plurality of first transistors in the diode-connected form, the plurality of first transistors being connected in series between the first amplification node and the first connection node.

4. The differential amplifier according to claim 3, wherein a first electrode of the first transistor is connected to the first amplification node, and a second electrode of the first transistor is connected to the first connection node,
wherein when the first transistor is a P-type transistor, a gate of the first transistor is connected to the second electrode of the first transistor; or when the first transistor is an N-type transistor, a gate of the first transistor is connected to the first electrode of the first transistor.

5. The differential amplifier according to claim 1, wherein
the isolation module comprises: a second transistor connected between the second amplification node and the second connection node, a gate of the second transistor being connected to the first connection node; and
the load module comprises: a third transistor and a fourth transistor, a first electrode of the third transistor being connected to the first connection node, a second electrode of the third transistor being configured with a first power signal, a gate of the third transistor being connected to the first electrode of the third transistor and a gate of the fourth transistor, a first electrode of the fourth transistor being connected to the second connection node, and a second electrode of the fourth transistor being configured with the first power signal,
wherein the third transistor and the fourth transistor have a same channel type, and the fourth transistor and the second transistor have different channel types; and the third transistor and the fourth transistor are both N-type transistors, and the second transistor is a P-type transistor.

6. The differential amplifier according to claim 1, wherein the differential input module comprises: a fifth transistor and a sixth transistor, a first electrode of the fifth transistor and a first electrode of the sixth transistor being both configured with the first bias current, a gate of the fifth transistor being connected to the first input terminal, a second electrode of the fifth transistor being connected to the first amplification node, a gate of the sixth transistor being connected to the second input terminal, and a second electrode of the sixth transistor being connected to the second amplification node; and
the fifth transistor and the sixth transistor have a same channel width-to-length ratio.

7. The differential amplifier according to claim 1, wherein the differential input module, the load module, and the isolation module all comprise thin-film transistors; and
the differential amplifier further comprises a voltage regulation module comprising thin-film transistors.

8. An operational amplifier circuit, comprising:
a differential amplifier;
an output module comprising a first control node and a third amplification node, the first control node being connected to an output terminal of the differential amplifier, and the third amplification node being configured to output an inverted amplified signal of a signal at the output terminal of the differential amplifier; and
a voltage control module comprising a second control node, an input node, and an output node, the second control node being configured with a fixed voltage signal, the input node being connected to the third amplification node, the output node being configured with a second bias current, and the output node serving as an output terminal of the operational amplifier circuit; and the voltage control module being controlled by the fixed voltage signal to stably output a voltage of the third amplification node at the output node.

9. The operational amplifier circuit according to claim 8, wherein the voltage control module comprises: an eighth transistor, a first electrode of the eighth transistor being connected to the output terminal of the operational amplifier circuit, and a second electrode of the eighth transistor being connected to the third amplification node; and a gate of the eighth transistor being configured with the fixed voltage signal.

10. The operational amplifier circuit according to claim 9, wherein the output module comprises: a ninth transistor, a gate of the ninth transistor being connected to the output terminal of the differential amplifier, a first electrode of the ninth transistor being connected to the third amplification node, and a second electrode of the ninth transistor being configured with a first power signal,
wherein the ninth transistor and the eighth transistor have a same channel type;
the ninth transistor and the eighth transistor are both N-type transistors; and
the fixed voltage signal has a voltage higher than a voltage of the control node.

11. The operational amplifier circuit according to claim 8, wherein the differential amplifier is configured with a first bias current; and
the operational amplifier circuit further comprises: a bias module comprising a first bias output node and a second bias output node, the first bias output node being configured to output the first bias current and the second bias output node being configured to output the second bias current.

12. The operational amplifier circuit according to claim 11, wherein the bias module comprises: a first current source and a second current source, an output terminal of the first current source being connected to the first bias output node, and an output terminal of the second current source being connected to the second bias output node;
the first current source comprises: a seventh transistor, a gate of the seventh transistor being configured with a bias voltage, a first electrode of the seventh transistor being configured with a second power signal, and a second electrode of the seventh transistor being connected to the output terminal of the first current source; and
the second current source comprises: a tenth transistor, a gate of the tenth transistor being configured with a bias voltage, a first electrode of the tenth transistor being configured with the second power signal, and a second electrode of the tenth transistor being connected to the output terminal of the second current source.

13. The operational amplifier circuit according to claim 8, further comprising: a storage module connected between the output terminal of the differential amplifier and the output terminal of the operational amplifier circuit,
the storage module comprising: a capacitor connected between the output terminal of the differential amplifier and the output terminal of the operational amplifier circuit.

14. The operational amplifier circuit according to claim 8, wherein the differential amplifier comprises:
a differential input module configured with a first bias current and comprising a first input terminal, a second input terminal, a first amplification node, and a second amplification node, the first input terminal being configured with an input signal, and the second input terminal being configured with a differential mode signal of the input signal; and the first amplification node being configured to output an inverted amplified signal of the input signal, and the second amplification node being configured to output an in-phase amplified signal of the input signal; and
a load module comprising a first connection node and a second connection node, the first connection node being connected to the first amplification node, and the second connection node being connected to the second amplification node; the second connection node serving as the output terminal of the differential amplifier; and
a voltage of the fixed voltage signal being different from a voltage at the output terminal of the differential amplifier.

15. The operational amplifier circuit according to claim 8, further comprising a differential amplifier, comprising:
a differential input module configured with a first bias current and comprising a first input terminal, a second input terminal, a first amplification node, and a second amplification node, the first input terminal being configured with an input signal, the second input terminal being configured with a differential mode signal of the input signal, the first amplification node being configured to output an inverted amplified signal of the input signal, and the second amplification node being configured to output an in-phase amplified signal of the input signal;
a load module comprising a first connection node and a second connection node, the first connection node being connected to the first amplification node, and the second connection node serving as an output terminal of the differential amplifier; and
an isolation module connected to the second amplification node and the second connection node, a control terminal of the isolation module being connected to the first connection node,
wherein a voltage variation at the first connection node is negatively correlated with a conduction level of the isolation module.

16. The operational amplifier circuit according to claim 15, wherein the second amplification node provides the fixed voltage signal, and the second control node is connected to the second amplification node;
or the differential amplifier comprises voltage regulation module connected to the first amplification node and the first connection node, the voltage regulation module being configured to stabilize a voltage at the first amplification node, the first amplification node provides the fixed voltage signal, and the second control node is connected to the first amplification node;
or the differential amplifier comprises the voltage regulation module connected to the first amplification node and the first connection node, the voltage regulation module being configured to stabilize a voltage at the first amplification node, the voltage regulation module comprising at least two first transistors connected in series in a diode-connected form, a connection node between any two adjacent first transistors provides the fixed voltage signal, and the second control node is connected to the connection node;
or the second control node is connected to a fixed voltage signal line for transmitting the fixed voltage signal, the fixed voltage signal having a voltage different from a voltage at the output terminal of the differential amplifier.

17. The operational amplifier circuit according to claim 8, wherein the differential amplifier, the output module, and the voltage control module all comprise thin-film transistors; and
the operational amplifier circuit further comprises a bias module comprising thin-film transistors.

18. An electronic device, comprising: an amplifier circuit comprising the differential amplifier according to claim 1.

19. The electronic device according to claim 18, wherein the electronic device is: a radio frequency identification device, a music player, or a display device.

20. The electronic device according to claim 18, wherein the electronic device is a display device; and the display device comprises: a driver chip, a plurality of data lines, and a plurality of amplifier circuits, the driver chip transmitting data signals to the data lines through the respective amplifier circuits.
